(19) United States
(12) Patent Application Publication
(10) Pub. No.: US 2026/0293312 A1
(43) Pub. Date: Sep. 24, 2026

(54) DRIVE CIRCUIT BOARD AND METHOD FOR MANUFACTURING DRIVE CIRCUIT BOARD

(71) Applicants: SHARP KABUSHIKI KAISHA, Osaka (JP); Sharp Display Technology Corporation, Kameyama City (JP)

(72) Inventors: TADAYOSHI MIYAMOTO, Osaka (JP); Sohtaroh TANAKA, Kameyama City (JP); Yoshinobu NAKAMURA, Kameyama City (JP); Toshihiro KANEKO, Kameyama City (JP)

(21) Appl. No.: 19/084,108

(22) Filed: Mar. 19, 2025

(51) Int. Cl. H10D 86/40; H10D 86/01

(52) U.S. Cl. CPC H10D 86/451; H10D 86/021

(57) ABSTRACT

A drive circuit board includes a circuit layer that includes a drive circuit and a drive electrode that is driven by a voltage applied from the drive circuit. The drive electrode includes a passive film having a first portion that is exposed to the outside on at least part of the surface of the drive electrode.

### BACKGROUND

### 1. Field

The present disclosure relates to a drive circuit board and a method for manufacturing the drive circuit board.

### 2. Description of the Related Art

In recent years, drive circuit boards including drive circuits having transistors can have been applied not only to display devices but a variety of fields and, thus, active research and development has been underway.

### SUMMARY

According to an aspect of the present disclosure, there is provided a drive circuit board including a circuit layer that includes a drive circuit and a drive electrode that forms layers together with the circuit layer and that is driven by a voltage applied from the drive circuit. The drive electrode includes a passive film having a first portion exposed to an outside on at least part of a surface of the drive electrode.

According to another aspect of the present disclosure, there is provided a method for manufacturing a drive circuit board. The method includes forming a circuit layer that includes a drive circuit and forming a drive electrode that forms layers together with the circuit layer and that is driven by a voltage applied from the drive circuit. The forming a drive electrode includes forming a passive film having a first portion exposed to an outside on at least part of a surface of the drive electrode.

### BRIEF DESCRIPTION OF THE DRAWINGS

FIG. 1A is a schematic side cross-sectional view of a drive circuit board according to a first embodiment;

FIG. 1B is a schematic enlarged view of part of the side cross section of the drive circuit board according to the first embodiment;

FIG. 2 is a flowchart of a method for manufacturing the drive circuit board according to the first embodiment;

FIGS. 3A to 3C are cross-sectional views of the steps of the method for manufacturing the drive circuit board according to the first embodiment;

FIGS. 4A and 4B are other cross-sectional views of the steps of the method for manufacturing the drive circuit board according to the first embodiment;

FIGS. 5A and 5B are other cross-sectional views of the steps of the method for manufacturing the drive circuit board according to the first embodiment;

FIG. 6 is other cross-sectional views of the steps of the method for manufacturing the drive circuit board according to the first embodiment;

FIG. 7 is another cross-sectional view of a step of the method for manufacturing the drive circuit board according to the first embodiment;

FIG. 8 is another cross-sectional view of a step of the method for manufacturing the drive circuit board according to the first embodiment;

FIG. 9 is another cross-sectional view of a step of the method for manufacturing the drive circuit board according to the first embodiment;

FIG. 10 is another cross-sectional view of a step of the method for manufacturing the drive circuit board according to the first embodiment;

FIG. 11 is another cross-sectional view of the step of the method for manufacturing the drive circuit board according to the first embodiment;

FIGS. 12A and 12B are enlarged cross-sectional views of the steps of the method for manufacturing the drive circuit board according to the first embodiment;

FIG. 13 is a schematic enlarged view of part of the side cross section of a drive circuit board according to a second embodiment; and

FIG. 14 is a schematic side cross-sectional view of a drive circuit board according to a third embodiment.

### DESCRIPTION OF THE EMBODIMENTS

### First Embodiment

Exemplary embodiments of the present disclosure are described below with reference to the accompanying drawings. Throughout the drawings, the same reference numerals are used for similar configurations, and the descriptions of the configurations are omitted. According to the present disclosure, for simplicity of illustration, some members identified by the same reference numeral may be scaled differently in the drawings and may be hatched in different patterns. However, the members illustrated in the drawings of the present disclosure are only examples, and the scales are not limited to those illustrated in the drawings. In addition, according to the present disclosure, the members with the same reference numerals but with different hatching patterns have the same configuration, as described above. Furthermore, in the drawings according to the present disclosure, when two members have substantially the same shape but, for example, different compositions, they may have the same hatching pattern although they are identified by different reference numerals.

### Drive Circuit Board: Overview

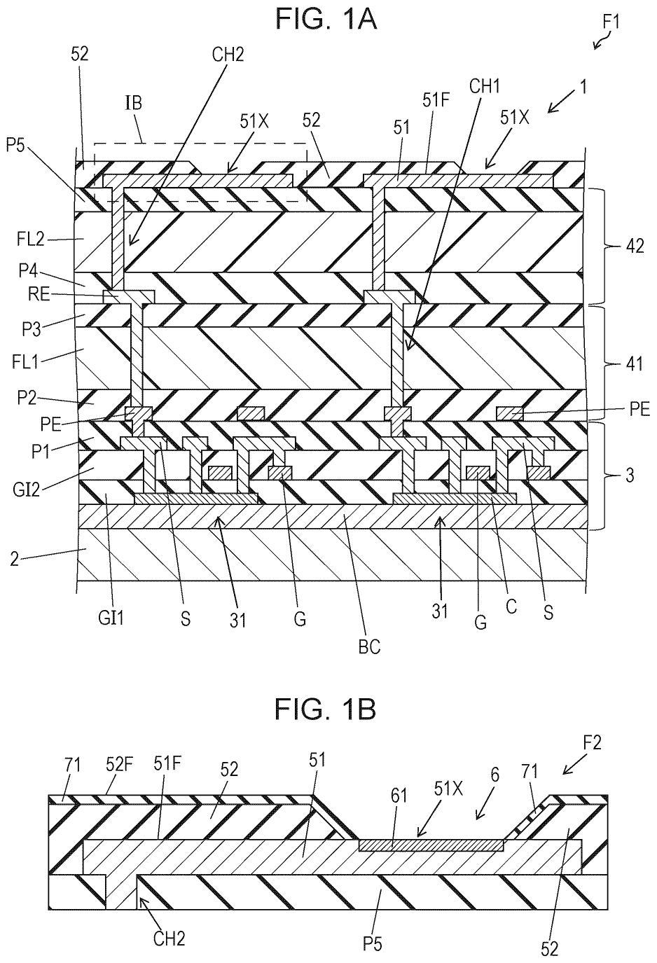

The drive circuit board according to the present embodiment is described in detail below with reference to FIGS. 1A and 1B. A schematic side cross-sectional view F1 of FIG. 1A is the schematic side cross-sectional view of a drive circuit board 1 according to the present embodiment. In particular, the schematic side cross-sectional view F1 illustrates the side cross section of the drive circuit board 1, which passes through two drive circuits 31 and two drive electrodes 51, each electrically connected to one of the two drive circuits 31 of the drive circuit board 1 (described below). A schematic enlarged view F2 of FIG. 1B is a schematic enlarged view of the side cross section of the drive circuit board 1 according to the present embodiment. In particular, the schematic enlarged view F2 is an enlarged view of a region IB illustrated in the schematic side cross-sectional view F1. That is, the schematic enlarged view F2 illustrates the drive electrode 51 and the surrounding vicinity of the drive electrode 51 (described below).

As illustrated in the schematic side cross-sectional view F1, the drive circuit board 1 according to the present embodiment includes a circuit layer 3, a power electrode PE, a first intervening layer 41, a relay electrode RE, a second intervening layer 42, a drive electrode 51, and an edge cover 52 on a substrate 2 stacked in this order.

### Drive Circuit Board: Substrate

The substrate 2 supports the layers of the drive circuit board 1 and may be a rigid substrate, such as a glass substrate. However, the substrate 2 is not limited thereto. For example, the substrate 2 may be a flexible substrate, such as a resin substrate.

### Drive Circuit Board: Circuit Layer: Drive Circuit

The circuit layer 3 includes the drive circuit 31 that drives the drive electrode 51 (described below) by applying a voltage to the drive electrode 51. In particular, according to the present embodiment, for example, the circuit layer 3 includes a plurality of drive circuits 31 each driving one of a plurality of the drive electrodes 51. Each of the drive circuits 31 is, for example, a transistor device and, in particular, a TFT device. The circuit layer 3 includes, for example, a channel layer C, a gate electrode layer G, and a source electrode layer S.

The channel layer C is a semiconductor layer including the channels of the drive circuit 31 and contains, for example, low-temperature polysilicon. A TFT device having channels and containing low-temperature polysilicon is effective for reducing the size thereof because of the high mobility of carriers in low-temperature polysilicon. However, the present embodiment is not limited thereto. For example, the channel layer C may include oxide semiconductors containing, for example, InGaZnO.

The gate electrode layer G is a conductive layer including the gate electrode of each of the drive circuits 31 and contains, for example, MoW. The source electrode layer S is a conductive layer including the source electrode and the drain electrode of each of the drive circuits 31 and has a stacked structure of Ti/Al/Ti, for example.

Each of the gate electrode and one of the source and drain electrodes of the drive circuit 31 is connected to a signal line to which signals are transmitted from a driver circuit (not illustrated). Thus, the drive circuit 31 controls the conduction of a signal applied to one of the source and drain electrodes to the other through the channel by using a signal applied to the gate electrode.

The other of the source and drain electrodes is electrically connected to the drive electrode 51 (described below). Thus, each of the drive circuits 31 controls application of voltage to the drive electrode 51 based on a signal from, for example, a driver circuit (not illustrated).

However, the present embodiment is not limited thereto, and each of the drive circuits 31 included in the circuit layer 3 may have a variety of configurations, including an existing well-known drive circuit configuration, as long as the voltage application to the drive electrode 51 can be controlled by the drive circuit 31. In particular, the drive circuit 31 according to the present embodiment may be either N-type TFT or P-type TFT.

### Drive Circuit Board: Circuit Layer: Interlayer Film

The circuit layer 3 further includes a base coat layer BC, a first gate insulating film GI1, a second gate insulating film GI2, and a first passivation film P1 that are stacked in this order from the side close to the substrate 2.

The base coat layer BC is located on the substrate 2 and has a function of reducing foreign substances (for example, moisture) that permeates from the substrate 2 toward the drive circuit 31. For example, the base coat layer BC includes an inorganic film of silicon oxide, silicon nitride, or the like.

The first gate insulating film GI1 insulates the channel layer C from the gate electrode layer G and contains, for example, silicon oxide. The first gate insulating film GI1 insulates the gate electrode layer G and the source electrode layer S. For example, the first gate insulating film GI1 may have a layered structure of silicon oxide and silicon nitride. Each of the source and drain electrodes of the drive circuit 31 is electrically connected to the channel through a contact hole that passes through the first gate insulating film GI1 and the second gate insulating film GI2 in the film thickness direction.

As illustrated in the schematic side cross-sectional view F1 of FIG. 1A, the source electrode layer S may have a portion connected to the gate electrode layer G via a contact hole that passes through the second gate insulating film GI2 in the film thickness direction. Thus, the application of a signal to one of the source and drain electrodes of the drive circuit 31 may be achieved via the gate electrode layer G.

According to the present disclosure, the “film thickness direction” of a given layer may be a direction that connects the lower surface to the upper surface of the layer or may be substantially the same as the normal direction of the lower surface or the upper surface of the layer. Alternatively, according to the present disclosure, the “film thickness direction” may be substantially the same as the normal direction of the upper surface of the substrate 2 or may be substantially the same as the stacking direction of the layers on the substrate 2.

The first passivation film P1 insulates the source electrode layer S from the power electrode PE (described below) and contains silicon nitride, for example. However, as described below, the power electrode PE is electrically connected to the other of the above-described source and drain electrodes of the drive circuit 31 via a contact hole that passes through the first passivation film P1 in the film thickness direction.

### Drive Circuit Board: Power Electrode

The power electrode PE is electrically connected to the other of the above-described source and drain electrodes of the drive circuit 31 via a contact hole that passes through the first passivation film P1 in the film thickness direction. Furthermore, the power electrode PE is electrically connected to the drive electrode 51 (described below), and a voltage is applied to the power electrode PE from a power supply (not illustrated). Thus, the power electrode PE increases the voltage applied to the drive electrode 51 when the drive electrode 51 is driven by the drive circuit 31.

When the drive circuit board 1 includes a plurality of the drive circuits 31 and drive electrodes 51, the power electrode PE is formed for each of the drive circuits 31 and drive electrodes 51. As illustrated in the schematic side cross-sectional view F1 of FIG. 1A, the power electrode PE may have a portion that is electrically independent from both the drive circuit 31 and the drive electrode 51.

### Drive Circuit Board: First Intervening Layer

The first intervening layer 41 includes a second passivation film P2, a first planarization film FL1, and a third passivation film P3 stacked in this order from the side close to the substrate 2.

The second passivation film P2 is located on the upper surfaces of the first passivation film P1 and the power electrode PE and has a layered structure of silicon oxide and silicon nitride, for example. The first planarization film FL1 is an organic film for planarizing unevenness on the upper surface of the second passivation film P2 caused by each of the layers from the second passivation film P2 to the substrate 2. The first planarization film FL1 contains acrylic resin, for example. The third passivation film P3 is located on the upper surface of the first planarization film FL1 and contains silicon nitride, for example.

### Drive Circuit Board: Relay Electrode

The relay electrode RE is located on the third passivation film P3 and inside of a first contact hole CH1 that passes through each of the layers of the first intervening layer 41 in the film thickness direction. The relay electrode RE is electrically connected to the power electrode PE via the first contact hole CH1. Thus, the relay electrode RE is electrically connected to the drive circuit 31 via the first contact hole CH1. When the drive circuit board 1 includes a plurality of the drive circuits 31 and drive electrodes 51, the relay electrode RE is formed for each of the drive circuits 31 and drive electrodes 51.

### Drive Circuit Board: Second Intervening Layer

The second intervening layer 42 includes a fourth passivation film P4, a second planarization film FL2, and a fifth passivation film P5 stacked in this order from the side close to the substrate 2.

The fourth passivation film P4 is located on the upper surfaces of the third passivation film P3 and the relay electrode RE and contains silicon nitride, for example. The second planarization film FL2 is an organic film for planarizing unevenness on the upper surface of the fourth passivation film P4 caused by the layers from the fourth passivation film P4 to the substrate 2. The second planarization film FL2 contains acrylic resin, for example.

The fifth passivation film P5 is located on the upper surface of the second planarization film FL2 and contains silicon nitride, for example. That is, the fifth passivation film P5 is an inorganic insulating layer located closer to the drive electrode 51 than the circuit layer 3.

Each of the first intervening layer 41 and second intervening layer 42 includes an inorganic film (for example, a passivation film) that generally reduces the permeation of a foreign substance, such as moisture, more than an organic film, and an organic film (for example, a planarization film) that improves the film forming property of an inorganic film by planarizing a surface on which the inorganic film is located. For this reason, the first intervening layer 41 and the second intervening layer 42 efficiently reduce permeation of moisture and the like into the drive circuit 31 of the circuit layer 3 from the side opposite to the side where the substrate 2 is present. In particular, since the drive circuit board 1 according to the present embodiment includes both the first intervening layer 41 and the second intervening layer 42, the permeation of moisture and the like into the drive circuit 31 of the circuit layer 3 from the side opposite to the side where the substrate 2 is present is reduced more efficiently.

### Drive Circuit Board: Drive Electrode

The drive electrode 51 is located on the fifth passivation film P5 and inside of a second contact hole CH2 that passes through the layers of the second intervening layer 42 in the film thickness direction. The drive electrode 51 is electrically connected to the relay electrode RE via the second contact hole CH2. Therefore, the drive electrode 51 is electrically connected to the relay electrode RE via the second contact hole CH2 and is further electrically connected to the drive circuit 31. As a result, each of the drive electrodes 51 is driven by the voltage applied from one of the drive circuits 31.

The drive electrode 51 contains a metal (for example, titanium). The drive electrode 51 containing titanium is highly resistant to a highly corrosive fluid, such as acidic solvent and alkalic solvent. For this reason, the drive circuit board 1 including the drive electrode 51 that contains titanium reduces deterioration of the drive electrode 51.

### Drive Circuit Board: Edge Cover

The edge cover 52 is located on a portion of the upper surface of each of the fifth passivation film P5 and the drive electrode 51. In particular, the edge cover 52 covers part of the peripheral portion of the drive electrode 51 in plan view and has an opening at the center portion of the drive electrode 51 in plan view. The drive electrode 51 thus has an exposed portion 51X of a surface 51F of the drive electrode 51 that is exposed from the edge cover 52 on the center side thereof in plan view. The edge cover 52 may be, for example, an insulating film containing silicon nitride.

The edge cover 52 covers the edge portion of the drive electrode 51 in plan view where the electric field concentrates when a voltage is applied to the drive electrode 51 by the drive circuit 31. This enables the edge cover 52 to reduce the effect of the concentration of electric fields at the edge portion of the drive electrode 51 in plan view.

According to the present embodiment, the fifth passivation film P5, which is an inorganic insulating layer, is located closer to the drive electrode 51 than the circuit layer, and the drive electrode 51 and part of the edge cover 52 are located on the fifth passivation film P5. Therefore, the fifth passivation film P5 reduces permeation of a foreign matter, such as moisture, in both the direction from the side opposite toward the side where the substrate 2 is present to the drive circuit 31 and the direction from the side where the substrate 2 is present toward the drive electrode 51.

### Passive Film

The structure of the drive electrode 51 and the structure in the surrounding vicinity of the drive electrode 51 according to the present embodiment are described in more detail below with reference to the schematic enlarged view F2 of FIG. 1B.

As illustrated in the schematic enlarged view F2, the drive electrode 51 has a passive film 6 on the surface 51F. The passive film 6 is an oxide film that is located on at least part of the surface 51F of the drive electrode 51 and that is formed by oxidation of the surface of a metal (for example, titanium) of the drive electrode 51. For example, the passive film 6 contains titanium oxide. The passive film 6 has a first portion 61 located on the exposed portion 51X of the surface 51F of the drive electrode 51 that is exposed from the edge cover 52. That is, the first portion 61 is exposed to the outside of the drive circuit board 1. When the drive circuit board 1 includes a plurality of the drive electrodes 51, each of the drive electrodes 51 has the passive film 6 on at least part of the surface 51F.

The passive film 6 is highly resistant to highly corrosive fluid, such as strong acid or strong alkali. For this reason, the passive film 6 having the first portion 61 exposed to the outside of the drive circuit board 1 reduces deterioration of the drive electrode 51 in the case where, for example, the drive electrode 51 is exposed to the above-described highly corrosive fluid. In particular, the first portion 61 is located at the exposed portion 51X where the surface 51F of the drive electrode 51 is exposed from the edge cover 52. Therefore, the drive circuit board 1 reduces the deterioration of the drive electrode 51 by using the passive film 6 while reducing the influence of the electric field concentration described above.

When the passive film 6 is an oxide film located on the surface 51F of the drive electrode 51, the passive film 6 can be easily formed by oxidation treatment of the drive electrode 51 (described below), which removes, for example, the process of separately forming a layer including the passive film 6. In particular, when the passive film 6 contains titanium oxide, which is an oxide film of the drive electrode 51 containing titanium, the passive film 6 is resistant to fluids of a wide range of pH, including strongly acidic fluids, thus further reducing deterioration of the drive electrode 51. In addition, since each of the plurality of drive electrodes 51 has the passive film 6, the drive circuit board 1 reduces the deterioration of only particular ones of the plurality of drive electrodes 51 and, thus, reduces differences in characteristics among the plurality of drive electrodes 51.

The edge cover 52 according to the present embodiment may have an oxide film 71 on at least part of the surface 52F. In particular, the edge cover 52 according to the present embodiment may have the oxide film 71 on the portion of the surface 52F that is exposed to the outside of the drive circuit board 1. Alternatively, the edge cover 52 may have the oxide film 71 on the portion of the surface 52F corresponding to the upper surface of the drive circuit board 1. When the edge cover 52 contains silicon nitride, the oxide film 71 may contain a mixture of silicon nitride and silicon oxide formed by replacing some of the nitrogen atoms of the silicon nitride with oxygen atoms.

### Method for Manufacturing Drive Circuit Board: Overview

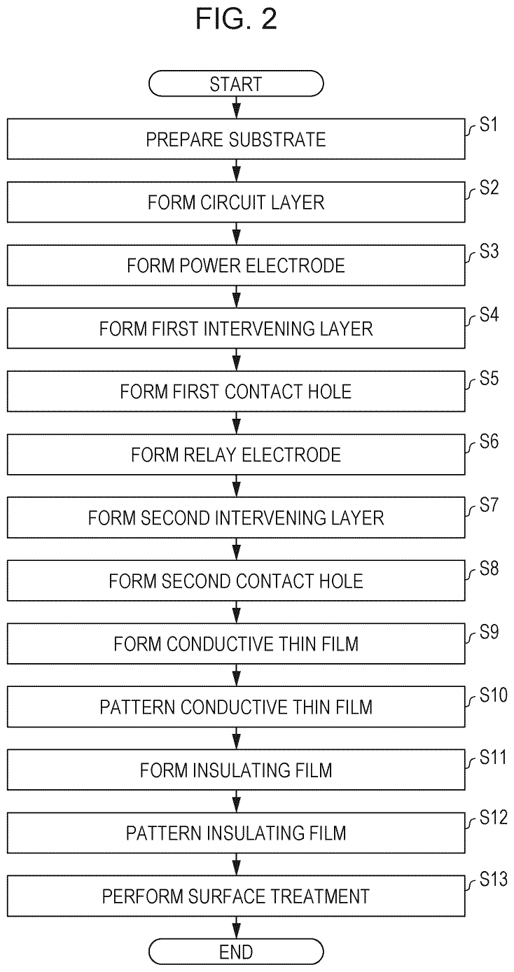

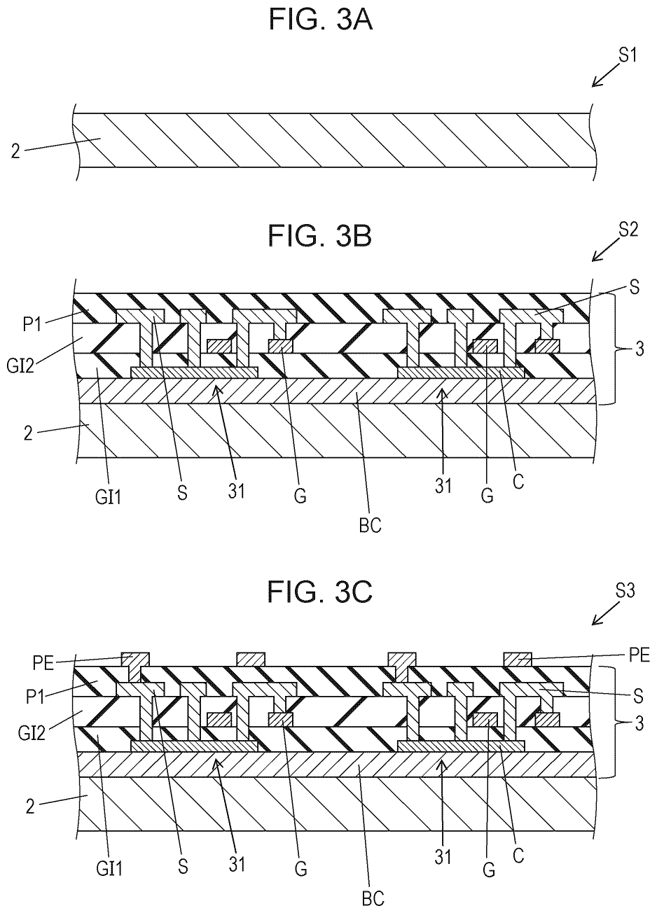

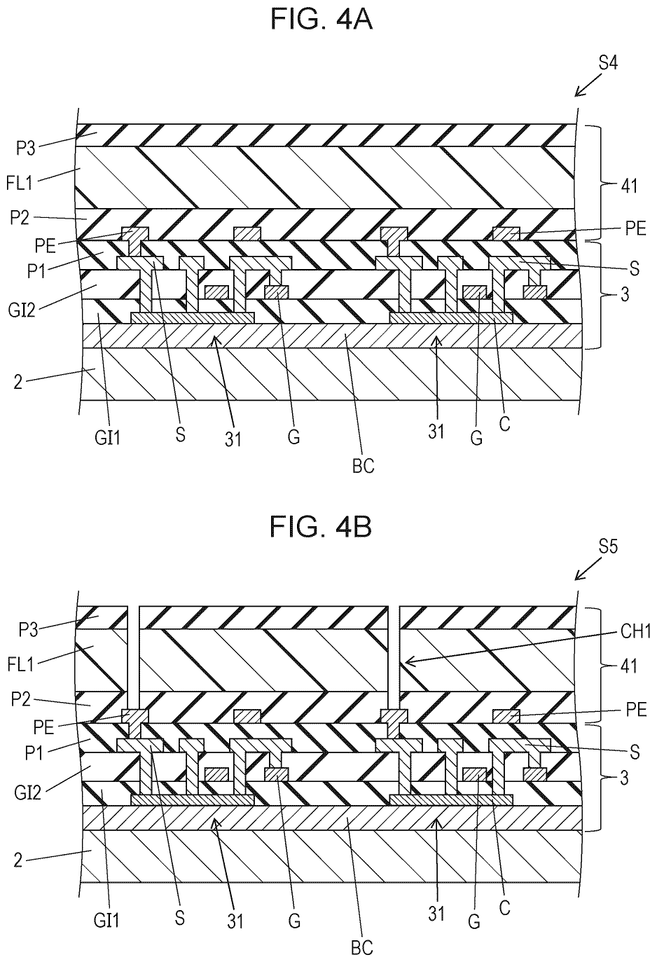

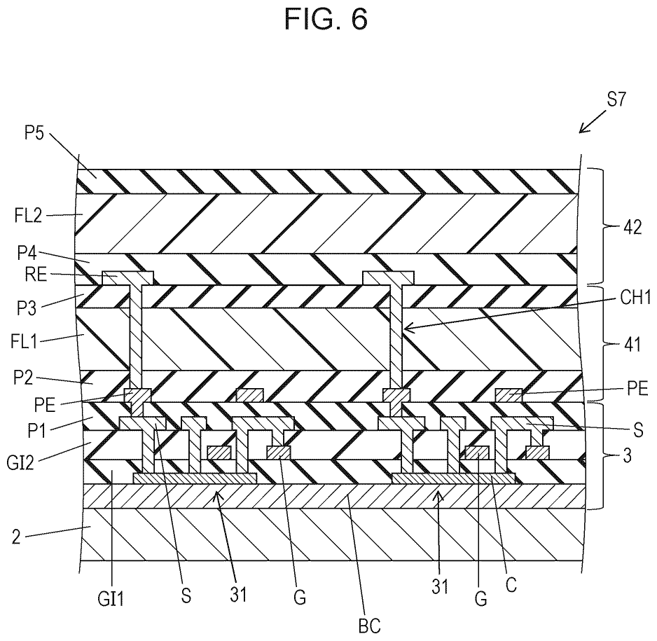

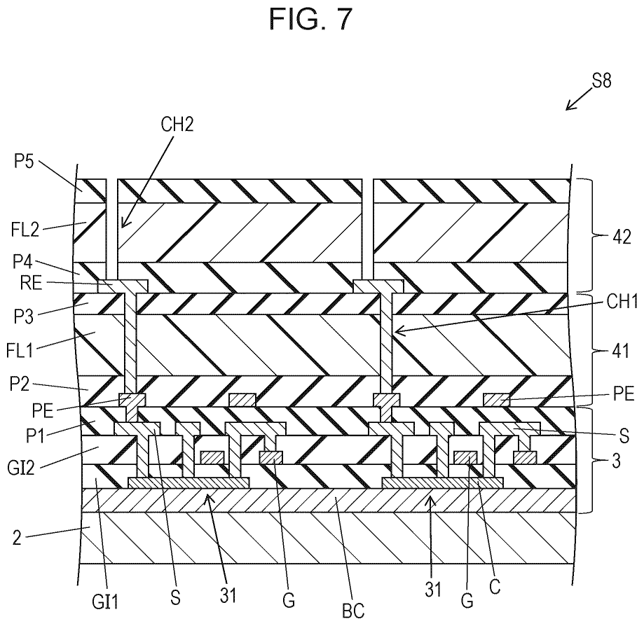

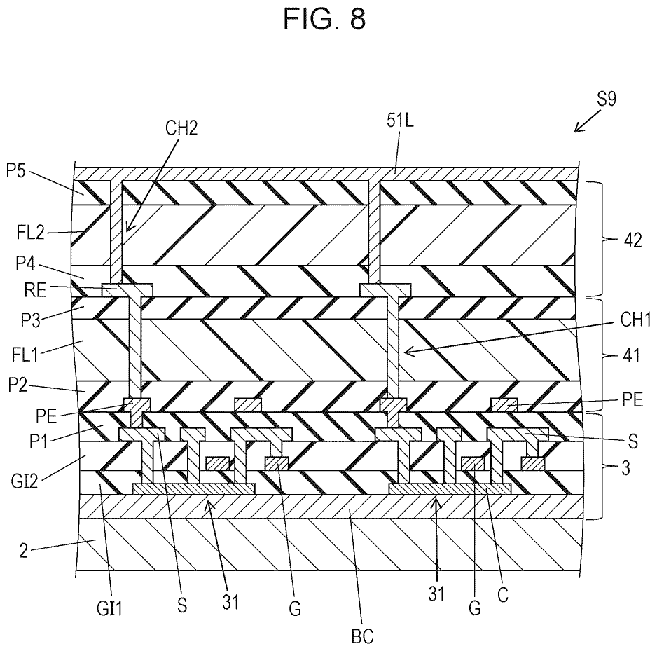

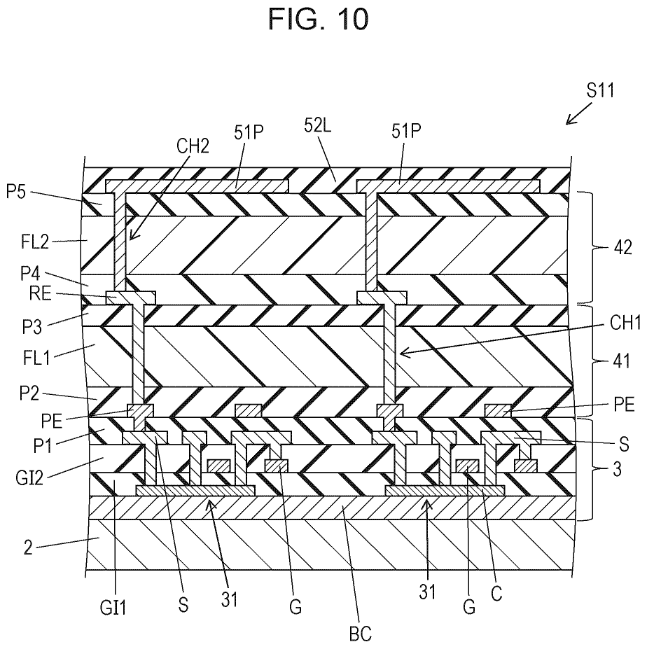

The method for manufacturing the drive circuit board 1 according to the present embodiment is described in detail below with reference to FIGS. 2 to 11. FIG. 2 is a flowchart of the method for manufacturing the drive circuit board 1 according to the present embodiment. FIGS. 3A to 11 are cross-sectional views of the steps of the method for manufacturing the drive circuit board 1 according to the present embodiment, each illustrating the side cross section at the position corresponding to the position of the side cross section of the schematic side cross-sectional view F1 in FIG. 1A.

### Method for Manufacturing Drive Circuit Board: Preparation of Substrate to Formation of Second Contact Hole

According to the method for manufacturing the drive circuit board 1 of the present embodiment, the substrate 2 is first prepared (step S1). In step S1, the substrate 2 of the same shape as the substrate 2 of the manufactured drive circuit board 1 may be prepared. Alternatively, a large-sized mother glass may be prepared as the substrate 2 in step S1 and, thereafter, the mother glass may be separated into pieces to produce a plurality of drive circuit boards 1.

Subsequently, the circuit layer 3 is formed on the substrate 2 (step S2). In step S2, film formation of each of the layers in the circuit layer 3 and the patterning of the thin film formed by the film formation may be performed repeatedly, starting from the side of the substrate 2. The patterning of the thin film may include formation of an opening, such as a contact hole, in the thin film. Thus, in step S2, a plurality of drive circuits 31 included by the circuit layer 3 are formed.

In step S2, film formation of each layer of the circuit layer 3 may be performed by a variety of film-forming methods, including sputtering. In addition, in step S2, patterning of the thin film formed through the film formation may be performed by a variety of methods, such as photolithography. Formation of the channel layer C in step S2 may include film formation and patterning of a semiconductor that is the material of the channel layer C and doping of the semiconductor.

Subsequently, the power electrode PE is formed on the circuit layer 3 (step S3). In step S3, for example, a contact hole is first formed in the first passivation film P1 at a position where the first passivation film P1 overlaps the source electrode or drain electrode of each of the drive circuits 31 in plan view. Thereafter, a thin film of a conductive material is formed inside of the contact hole and on the upper surface of the first passivation film P1 by sputtering or another technique, and the thin film is patterned. Thus, the power electrode PE is formed so as to be located on the first passivation film P1 or electrically connected to the drive circuit 31.

Subsequently, the first intervening layer 41 is formed on the circuit layer 3 and the power electrode PE (step S4). In step S4, film formation of each of the layers of the first intervening layer 41 may be performed in sequence from the side closer to the circuit layer 3 and the power electrode PE. For example, the film formation of the second passivation film P2 and the third passivation film P3 may be performed by sputtering. The film formation of the first planarization film FL1 may be performed by coating, such as the slit coat method.

Subsequently, the first contact hole CH1 is formed so as to pass through the layers of the first intervening layer 41 in the film thickness direction (step S5). In particular, in step S5, photolithography is used to form an opening that passes through the layers of the first intervening layer 41 in the film thickness direction at each of positions that overlap the power electrodes PE to be electrically connected to the drive circuits 31 in plan view.

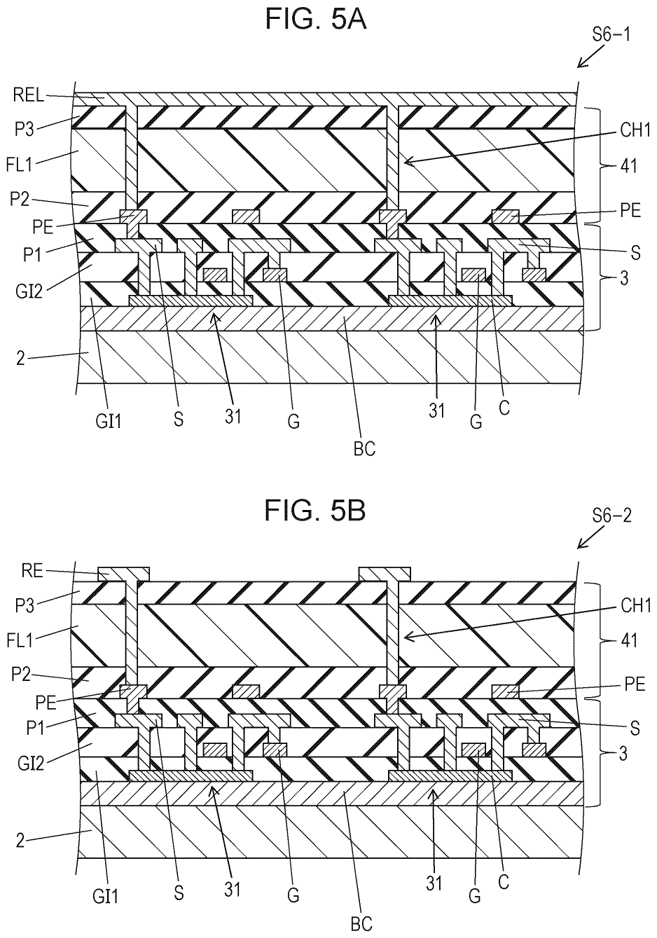

Subsequently, the relay electrode RE is formed on the first intervening layer 41 (step S6). In step S6, for example, a thin film REL of a conductive material is first formed inside of the first contact hole CH1 and on the upper surface of the third passivation film P3 by, for example, sputtering, as illustrated in step S6-1 of FIG. 5A. As a result, the thin film REL is in contact with each of the power electrodes PE through the first contact hole CH1. Subsequently, as illustrated in step S6-2 of FIG. 5B, the thin film REL is patterned to form the relay electrode RE. In the patterning, the thin film REL is made to remain in the first contact hole CH1. As a result, in step S6, a plurality of the relay electrodes RE each electrically connected to one of the drive circuits 31 are formed.

Subsequently, the second intervening layer 42 is formed on the first intervening layer 41 and on the power electrode PE (step S7). In step S7, film formation of each of the layers of the second intervening layer 42 may be performed in sequence from the side closer to the first intervening layer 41 and the power electrode PE. For example, film formation of the fourth passivation film P4 and the fifth passivation film P5 may be performed by, for example, sputtering. Film formation of the second planarization film FL2 may be performed by coating, such as the slit coat method.

Subsequently, the second contact hole CH2 is formed so as to pass through the layers of the second intervening layer 42 in the film thickness direction (step S8). In particular, in step S8, photolithography is used to form an opening that passes through the layers of the second intervening layer 42 in the film thickness direction at each of positions that overlap the relay electrodes RE in plan view.

### Method for Manufacturing Drive Circuit Board: Formation and Patterning of Conductive Thin Film

Subsequently, a conductive thin film 51L containing the material of the drive electrode 51 is formed inside of the second contact hole CH2 and on the upper surface of the fifth passivation film P5 (step S9). In step S9, the conductive thin film 51L is formed by, for example, sputtering. As a result, the conductive thin film 51L is in contact with each of the relay electrodes RE via the second contact hole CH2.

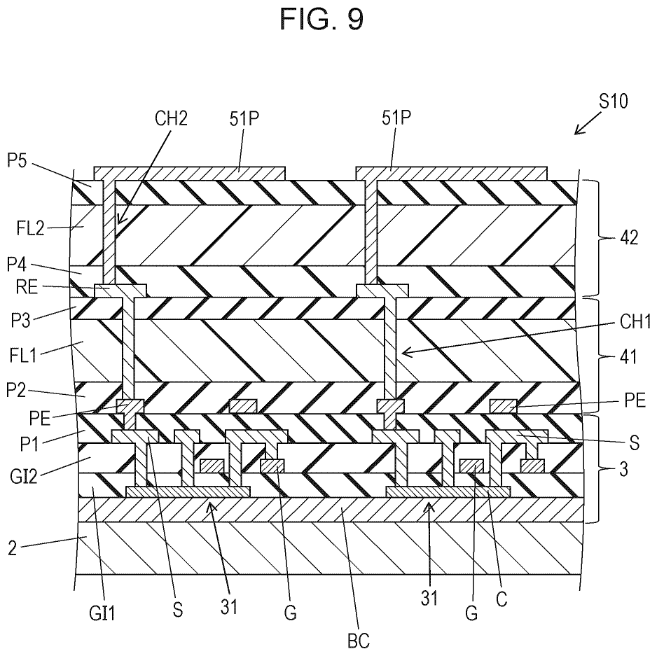

Subsequently, the conductive thin film 51L is patterned (step S10). In step S10, the conductive thin film 51L is made to remain in the second contact hole CH2. As a result, a plurality of drive electrodes 51P illustrated in FIG. 9 are formed in step S10. Each of the drive electrodes 51P is electrically connected to one of the drive circuits 31 via the second contact hole CH2, the relay electrode RE, the first contact hole CH1, and the power electrode PE. The drive electrode 51P has the same configuration as the drive electrode 51 except that it does not have a passive film 6 on its surface.

Thus, in step S10, the drive electrode 51P is formed so as to form layers together with the circuit layer 3 and be driven by the voltage applied from the drive circuit 31. In particular, in step S10, a plurality of the drive electrodes 51P are formed, each driven by one of the plurality of drive circuits 31.

### Method for Manufacturing Drive Circuit Board: Formation and Patterning of Insulating Film

Subsequently, an insulating film 52L containing the material of the edge cover 52 is formed on the surface 51F of drive electrode 51P and on the upper surface of the fifth passivation film P5 (step S11). In step S11, the insulating film 52L is formed by sputtering, for example.

Subsequently, the insulating film 52L is patterned (step S12). In particular, in step S12, a portion of the insulating film 52L located adjacent to the peripheral edge of the drive electrode 51P in plan view is made to remain, while a portion located adjacent to the center of the drive electrode 51P is removed in plan view.

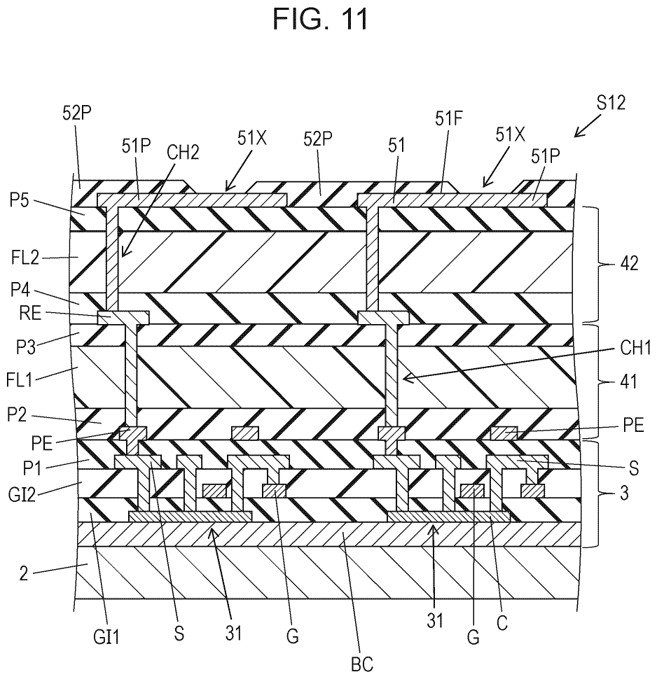

As a result, an edge cover 52P illustrated in FIG. 11 is formed in step S12. In particular, the edge cover 52P has the same configuration as the edge cover 52 except that the edge cover 52P does not have the oxide film 71 on the surface 52F. Thus, in step S12, the edge cover 52P is formed that covers part of the peripheral side of the drive electrode 51P in plan view. That is, in step S12, at the center portion of the drive electrode 51P in plan view, the exposed portion 51X exposed from the edge cover 52P is formed on the surface 51F of the drive electrode 51P.

### Method for Manufacturing Drive Circuit Board: Formation of Passive Film by Surface Treatment

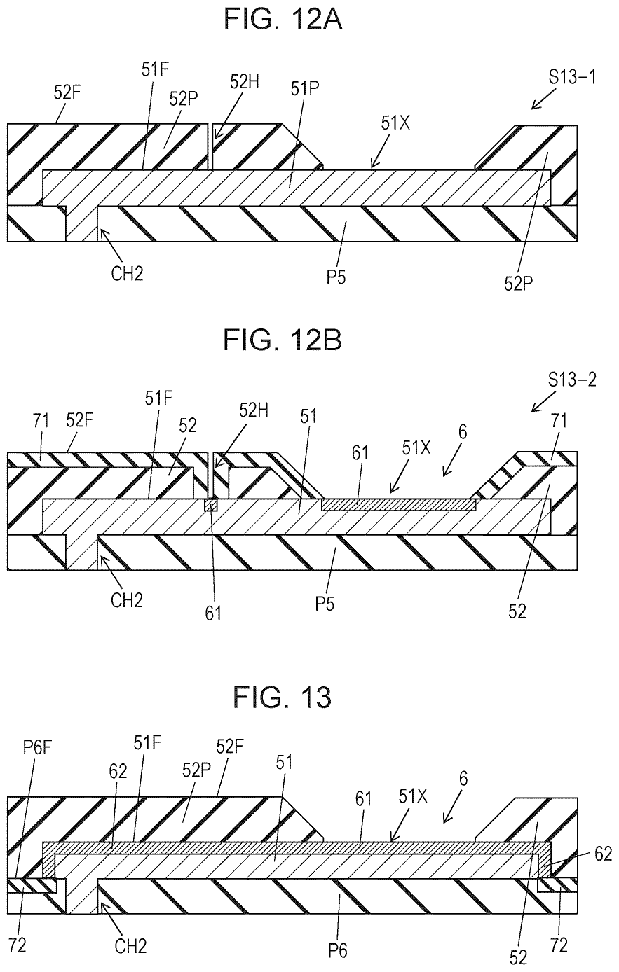

Subsequently, surface treatment is performed on the surface 52F of the edge cover 52P and the exposed portion 51X of the surface 51F of the drive electrode 51P that is exposed from the edge cover 52P (step S13). The surface treatment in step S13 is described in more detail below with reference to FIGS. 12A and 12B. FIGS. 12A and 12B are enlarged cross-sectional views of the steps of the method for manufacturing the drive circuit board 1 according to the present embodiment, and in particular, is enlarged side cross-sectional views of step S13. Both of the enlarged cross-sectional views of the steps illustrated in FIGS. 12A and 12B are enlarged views at the positions corresponding to those in the schematic enlarged view F2 of FIG. 1B.

As illustrated in step S13-1 of FIG. 12A, immediately before step S13 is performed, the drive electrode 51P has no passive film 6 on the surface 51F having the exposed portion 51X, and the edge cover 52P has no oxide film 71 on the surface 52F. At this time, in step S13, the surface treatment is performed on at least the exposed portion 51X of the drive electrode 51P.

The surface treatment in step S13 may include, for example, exposure of the portion of the drive electrode 51P that has the surface 51F to ozone water. In this case, the surface treatment in step S13 may be application of ozone water to the location including the exposed portion 51X and the upper surface of the edge cover 52P by any one of a variety of application methods, such as the spin coating method. Ozone water may be produced, for example, by dissolving ozone gas in pure water at a concentration of 20 ppm or higher and 100 ppm or lower. After the exposure to the above-described ozone water, the portion exposed to the ozone water may be washed and dried.

Alternatively, the surface treatment in step S13 may include, for example, exposure of a portion of the drive electrodes 51P including the surface 51F to oxygen plasma. In this case, the surface treatment in step S13 may be performed by placing the layers including the substrate 2 to the edge cover 52P in a vacuum chamber and injecting oxygen plasma into the vacuum chamber. After the above-described exposure to oxygen plasma is performed, the portion exposed to the oxygen plasma may be washed and dried.

When the surface treatment in step S13 includes exposure of a portion of the drive electrodes 51P including the surface 51F to ozone water, the surface treatment can be performed easily in a low-temperature process. In contrast, when the surface treatment in step S13 includes exposure of a portion of the drive electrodes 51P including the surface 51F to oxygen plasma, unevenness of the surface treatment can be reduced, and the surface treatment can be performed on the entire surfaces of the layers from the substrate 2 to the edge cover 52P at one time.

As illustrated in step S13-2 of FIG. 12B, the portion of the surface 51F of the drive electrode 51P that has undergone surface treatment in step S13 is oxidized and turns into the passive film 6. In particular, the exposed portion 51X of the surface 51F of the drive electrode 51P that is exposed from the edge cover 52P turns into the first portion 61 of the passive film 6. In addition, the portion of the surface 52F of the edge cover 52P that has undergone the surface treatment in step S13 is oxidized and turns into the oxide film 71.

As described above, in step S13, the drive electrode 51 having the passive film 6 on the surface 51F and the edge cover 52 having the oxide film 71 on the surface 52F are formed. That is, the formation of the drive electrode 51 includes the formation of the passive film 6 having the first portion 61 exposed to the outside on at least part of the surface 51F of the drive electrode 51. In the formation of the passive film 6 according to the present embodiment, the first portion 61 is formed on the exposed portion 51X. In addition, according to the present embodiment, the formation of the passive film 6 is performed after the formation of the edge cover 52P.

As described above, the manufacture of the drive circuit board 1 is completed. The drive circuit board 1 manufactured by the above-described method includes the first portion 61 of the passive film 6 in the exposed portion 51X of the drive electrode 51, thus reducing deterioration of the drive electrode 51 due to corrosion or the like.

### Method for Manufacturing Drive Circuit Board: Supplementary Note

According to the present embodiment, the method for manufacturing the drive circuit board 1 includes patterning of the conductive thin film 51L containing the material of the drive electrode 51 and patterning of the insulating film 52L containing the material of the edge cover 52. If part of each of the thin films is removed by, for example, dry etching in the patterning processes, halogen atoms, such as fluorine atoms, may remain on the surface 51F of the drive electrode 51P.

If the drive electrode 51P having halogen atoms remaining on the surface 51F is brought into contact with a highly corrosive fluid, such as strong acid, the halogen atoms may accelerate the corrosion of the metal material of the drive electrode 51P. For this reason, even if the drive electrode 51P contains a material (for example, titanium) that has particularly high resistance to corrosion among metal materials, deterioration of the drive electrode 51P caused by corrosion may occur.

According to the method for manufacturing the drive circuit board 1 of the present embodiment, after the patterning described above, the passive film 6 is formed on the surface 51F of the drive electrode 51P by surface treatment performed on at least part of the surface 51F of the drive electrode 51P. The surface treatment includes oxidation treatment of the surface 51F of the drive electrode 51P using ozone water or oxygen plasma.

Thus, even when halogen atoms are located inside of the surface 51F of the drive electrode 51P, the halogen atoms are replaced with oxygen atoms by the above-described surface treatment and, therefore, the halogen atoms are removed from the surface 51F. For this reason, the drive electrode 51P formed by the above-described method reduces deterioration caused by corrosion or the like, even when the drive electrode 51P is formed through the patterning described above.

As described above, the formation of the passive film 6, that is, the surface treatment described above, is performed after the formation of the edge cover 52P. For this reason, the above-described surface treatment can be performed following the above-described patterning, for example, with each of the layers on the substrate 2 stored inside of a vacuum chamber that is used for patterning of the insulating film 52L when the edge cover 52P is formed. This simplifies the method for manufacturing the drive circuit board 1 or reduces the tact time in the present embodiment.

As illustrated in step S13-1 of FIG. 12A, a pinhole 52H may be formed in the edge cover 52P due to defects during film formation. For example, the pinhole 52H passes through from the upper surface of edge cover 52P to the upper surface of drive electrode 51P in the film thickness direction. Therefore, part of the surface 51F of the drive electrode 51P may be exposed from the pinhole 52H.

Even in this case, the surface treatment is performed in step S13 on the portion of the surface 51F of the drive electrode 51 that is exposed from the pinhole 52H. Therefore, even in the above-described case, as illustrated in step S13-2 of FIG. 12B, the surface treatment in step S13 forms the first portion 61 of the passive film 6 on the exposed portion that is exposed from the pinhole 52H in the surface 51F of the drive electrode 51.

Therefore, according to the method for manufacturing the drive circuit board 1 of the present embodiment, even when a pinhole 52H is formed in the edge cover 52P, the drive circuit board 1 can be manufactured that exhibits reduced deterioration due to corrosion of part of the surface 51F of the drive electrode 51 that is exposed from the pinhole 52H. In step S13, the oxide film 71 may also be formed on the inner surface of the pinhole 52H of the edge cover 52.

The edge cover 52 having the oxide film 71 on at least part of the surface 52F can be formed by performing the surface treatment in step S13 not only on the exposed portion 51X of the drive electrode 51P but also on the surface 52F of the edge cover 52P, as described above. Therefore, in step S13, the application of ozone water to the position including the surface 52F of the edge cover 52P described above or the exposure of each of the layers on the substrate 2 to oxygen plasma or the like can be employed to form the passive film 6. That is, local surface treatment to be performed only on the exposed portion 51X is unnecessary to form the passive film 6. As a result, the drive circuit board 1 can be manufactured by a simpler manufacturing method.

### Second Embodiment

### Surface Treatment Prior to Edge Cover Formation

A drive circuit board according to the present embodiment is described in detail below with reference to FIG. 13. FIG. 13 is a schematic enlarged view of the side cross section of a drive circuit board 1 according to the present embodiment. In particular, FIG. 13 is a schematic enlarged view of the side cross section of the drive circuit board 1 according to the present embodiment at the position corresponding to the region IB illustrated in the schematic enlarged view F2 of FIG. 1B.

As compared with the drive circuit board 1 according to the above-described embodiment, the drive circuit board 1 according to the present embodiment includes the edge cover 52P described above instead of the edge cover 52. That is, according to the present embodiment, the edge cover 52P does not have the oxide film 71 on the surface 52F.

In addition, as compared with the drive circuit board 1 according to the above-described embodiment, the configuration of the drive circuit board 1 according to the present embodiment differs from that according to the above-described embodiment in that the passive film 6 has a second portion 62 in addition to the first portion 61. The second portion 62 is located on the surface 51F of the drive electrode 51 and, in particular, at least partially between the drive electrode 51 and the edge cover 52P. Thus, for example, as illustrated in FIG. 13, the second portion 62 is covered by the edge cover 52P without being exposed from the edge cover 52P.

In addition, as compared with the drive circuit board 1 according to the above-described embodiment, the drive circuit board 1 according to the present embodiment includes, as an inorganic insulating layer, a sixth passivation film P6 instead of the fifth passivation film P5. The sixth passivation film P6 has an oxide film 72 on a surface P6F, which is the upper surface, at a position closer to the periphery than the drive electrode 51 in plan view. That is, the sixth passivation film P6, which is an inorganic insulating layer, has an oxide film 72 on at least part of the surface P6F on the side closer to the drive electrode 51.

The sixth passivation film P6 may contain the same material as the fifth passivation film P5. When the sixth passivation film P6 contains silicon nitride, the oxide film 72 may contain a mixture of silicon nitride and silicon oxide that is formed by replacing some of the nitrogen atoms in the silicon nitride with oxygen atoms.

Except for the configuration described above, the drive circuit board 1 according to the present embodiment has the same configuration as the drive circuit board 1 according to the above-described embodiment. Therefore, according to the present embodiment, the passive film 6 is located on a portion, which includes the exposed portion 51X, of the surface 51F of the drive electrode 51 of the drive circuit board 1. As a result, according to the drive circuit board 1 of the present embodiment, the passive film 6 reduces the deterioration of the drive electrode 51.

The passive film 6 according to the present embodiment has the second portion 62 located between the drive electrode 51 and the edge cover 52P, in addition to the first portion 61 located on the exposed portion 51X of the surface 51F of the drive electrode 51. Therefore, the passive film 6 according to the present embodiment can protect the drive electrode 51 from deterioration, such as corrosion caused by a highly corrosive fluid (for example, strong acid) that permeates the edge cover 52P. As a result, according to the drive circuit board 1 of the present embodiment, the deterioration of the drive electrode 51 is further reduced.

The drive circuit board 1 according to the present embodiment can be manufactured by the same method for manufacturing the drive circuit board 1 according to the above-described embodiment, except that step S13 is performed between steps S10 and S11. That is, according to the present embodiment, the formation of the passive film 6 is performed prior to the formation of the edge cover 52P.

Therefore, according to the present embodiment, step S12 is performed with the passive film 6 formed on the surface 51F of the drive electrode 51. As a result, according to the method for manufacturing the drive circuit board 1 of the present embodiment, the passive film 6 reduces deterioration of the surface 51F of the drive electrode 51 caused by dry etching or the like employed in step S12.

As described above, the sixth passivation film P6 having an oxide film 72 at least partially on the surface P6F can be formed by performing the surface treatment in step S13 not only on the surface 51F but also on the surface P6F. Therefore, in step S13, the application of ozone water to the location including the surface P6F described above or the exposure of each of the layers on the substrate 2 to oxygen plasma or the like can be employed to form the passive film 6. That is, local surface treatment to be performed only on the surface 51F is unnecessary to form the passive film 6. As a result, the drive circuit board 1 according to the present embodiment can be manufactured by a simpler manufacturing method.

In the drive circuit board 1 according to the present embodiment and the drive circuit board 1 according to the above-described embodiment, one of the inorganic insulating layer and the edge cover includes an oxide film on at least part of its surface. However, the configuration is not limited thereto. In the drive circuit board 1 described above, each of the inorganic insulating layer and the edge cover may have an oxide film at least partially on its surface. In this case, step S13 may be performed both between steps S10 and S11 and after step S12. This results in the drive circuit board 1 including the drive electrode 51 having a more resistant passive film 6 on the surface 51F because the surface 51F of the drive electrode 51 undergoes two oxidation processes.

### Third Embodiment

### Removal of Second Intervening Layer

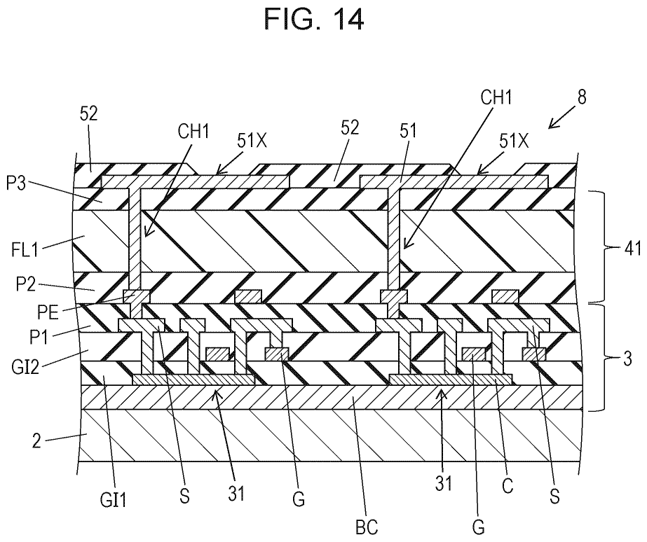

A drive circuit board according to the present embodiment is described in detail below with reference to FIG. 14. FIG. 14 is a schematic side cross-sectional view of a drive circuit board 8 according to the present embodiment. In particular, FIG. 14 illustrates the side cross section of the drive circuit board 8 according to the present embodiment at a position corresponding to the side cross section illustrated in the schematic side cross-sectional view F1 of FIG. 1A.

The configuration of the drive circuit board 8 according to the present embodiment differs from that of the drive circuit board 1 according to any one of the above-described embodiments in that the drive circuit board 8 has the configuration that does not include the relay electrode RE and the second intervening layer 42. Therefore, according to the present embodiment, the drive electrode 51 is located on the third passivation film P3, which is an inorganic insulating film of the first intervening layer 41. Each of the drive electrodes 51 is electrically connected to one of the power electrodes PE and is further electrically connected to one of the drive circuits 31 through the first contact hole CH1 that passes through the layers of the first intervening layer 41 in the film thickness direction.

Except for the configuration described above, the drive circuit board 8 according to the present embodiment has the same configuration as the drive circuit board 1 according to any one of the above-described embodiments. Therefore, according to the drive circuit board 8 of the present embodiment, the passive film 6 reduces deterioration of the drive electrode 51. Furthermore, since the drive circuit board 8 does not include the second intervening layer 42, the size of the drive circuit board 8 can be reduced in the film thickness direction, and miniaturization of the drive circuit board 8 can be achieved.

As compared with the method for manufacturing the drive circuit board 1 according to any one of the above-mentioned embodiments, the drive circuit board 8 according to the present embodiment can be manufactured by the same method except for removal of steps S6 to S8. As a result, the manufacturing processes of the drive circuit board 8 can be simplified. Alternatively, a reduction in the manufacturing cost or tact time can be achieved.

The drive circuit board 8 according to the present embodiment has a reduced size between the circuit layer 3 and the drive electrode 51 in the film thickness direction. Therefore, when the exposed portion 51X of the drive electrode 51 of the drive circuit board 8 is exposed to a fluid, the distance between the fluid and the drive circuit 31 of the circuit layer 3 is less than that in the drive circuit board 1 according to any one of the embodiments described above.

However, according to the present embodiment, the passive film 6 is located on the surface 51F of the drive electrode 51 and, therefore, the deterioration of the drive electrode 51 is reduced. For this reason, according to the drive circuit board 8, while the distance between the circuit layer 3 and the drive electrode 51 is reduced, permeation of the fluid to the drive circuit 31 of the circuit layer 3 through the deteriorated drive electrode 51 is reduced. As a result, the drive circuit board 8 achieves both miniaturization thereof and reduced deterioration of the drive circuit 31.

### SUMMARY

According to a first aspect of the present disclosure, a drive circuit board includes a circuit layer that includes a drive circuit and a drive electrode that forms layers together with the circuit layer and that is driven by a voltage applied from the drive circuit, and the drive electrode includes a passive film having a first portion exposed to an outside on at least part of a surface of the drive electrode.

According to a second aspect of the present disclosure, in the first aspect described above, the drive circuit board may further include an edge cover that covers part of the peripheral portion of the drive electrode in plan view. The drive electrode may have an exposed portion exposed from the edge cover at the center portion of the drive electrode in plan view, and the first portion may be located at the exposed portion of the surface of the drive electrode.

According to a drive circuit board of a third aspect of the present disclosure, in the second aspect described above, the edge cover may have an oxide film on at least part of a surface of the edge cover.

According to the drive circuit board of a fourth aspect of the present disclosure, in the second or third aspect described above, the passive film may have a second portion located at least

### Partially Between the Drive Electrode and the Edge Cover.

According to a fifth aspect of the present disclosure, in any one of the second to fourth aspects described above, the drive circuit board may further include an inorganic insulating layer located closer to the drive electrode than the circuit layer, and the drive electrode and part of the edge cover may be located on the inorganic insulating layer.

According to a drive circuit board of a sixth aspect of the present disclosure, in the fifth aspect described above, the inorganic insulating layer may have an oxide film on at least part of a surface of the inorganic insulating layer adjacent to the drive electrode.

According to a drive circuit board of a seventh aspect of the present disclosure, in any one of the first to sixth aspects described above, the drive electrode may contain a metal, and the passive film may be an oxide film located on at least part of the surface of the drive electrode.

According to a drive circuit board of an eighth aspect of the present disclosure, in the seventh aspect described above, the drive electrode may contain titanium, and the passive film may contain titanium oxide.

According to a drive circuit board of a ninth aspect of the present disclosure, in any one of the first to eighth aspects described above, the drive electrode may be provided in a plurality, and the drive circuit may be provided in a plurality. The circuit layer may include the plurality of drive circuits each driving one of the plurality of drive electrodes, and each of the plurality of drive electrodes may have the passive film on at least part of the surface of the drive electrode.

According to a tenth aspect of the present disclosure, in any one of the first to ninth aspects described above, the drive circuit board may further include a first intervening layer between the drive electrode and the circuit layer, a relay electrode that is electrically connected to the drive circuit via a first contact hole passing through the first intervening layer in a film thickness direction of the first intervening layer, and a second intervening layer between the relay electrode and the drive electrode. The drive electrode may be electrically connected to the relay electrode via a second contact hole passing through the second intervening layer in a film thickness direction of the second intervening layer.

According to an eleventh aspect of the present disclosure, in any one of the first to ninth aspects described above, the drive circuit board may further include a first intervening layer between the drive electrode and the circuit layer, and the drive electrode may be electrically connected to the drive circuit via a first contact hole passing through the first intervening layer in a film thickness direction of the first intervening layer.

According to a twelfth aspect of the present disclosure, a method for manufacturing a drive circuit board includes forming a circuit layer that includes a drive circuit and forming a drive electrode that forms layers together with the circuit layer and that is driven by a voltage applied from the drive circuit. The forming a drive electrode includes forming a passive film having a first portion exposed to an outside on at least part of a surface of the drive electrode.

According to a thirteenth aspect of the present disclosure, in the twelfth aspect described above, the method for manufacturing a drive circuit board may further include forming an edge cover that covers part of the peripheral portion of the drive electrode in plan view. The drive electrode may have an exposed portion exposed from the edge cover at the center portion of the drive electrode in plan view, and the first portion may be formed at the exposed portion in the forming a passive film.

According to a method for manufacturing a drive circuit board of a fourteenth aspect of the present disclosure, in the thirteenth aspect described above, the forming an edge cover may include forming an insulating film containing the material used for the edge cover and forming the exposed portion by patterning the insulating film.

According to a method for manufacturing a drive circuit board of a fifteenth aspect of the present disclosure, in the thirteenth or fourteenth aspect described above, the forming a passive film may be performed after the forming an edge cover.

According to a method for manufacturing a drive circuit board of a sixteenth aspect of the present disclosure, in any one of the thirteenth to fifteenth aspects described above, the forming a passive film may be performed before the forming an edge cover.

According to a method for manufacturing a drive circuit board of a seventeenth aspect of the present disclosure, in any one of the twelfth to sixteenth aspects described above, the forming a passive film may include exposing a portion including a surface of the drive electrode to ozone water.

According to a method for manufacturing a drive circuit board of an eighteenth aspect of the present disclosure, in any one of the twelfth to sixteenth aspects described above, the forming a passive film may include exposing a portion including a surface of the drive electrode to oxygen plasma.

According to a method for manufacturing a drive circuit board of a nineteenth aspect of the present disclosure, in any one of the twelfth to eighteenth aspects described above, the forming a drive electrode may include forming a plurality of the drive electrodes, the forming the circuit layer may include forming a plurality of the drive circuits each driving one of the plurality of drive electrodes, and the forming a plurality of drive electrodes may include forming a conductive thin film containing the material used for the drive electrodes and patterning the conductive thin film.

The present disclosure is not limited to the above-described embodiments, and various changes can be made within the scope of the claims, and embodiments obtained by combining technical measures disclosed in different embodiments as appropriate are also encompassed in the technical scope of the present disclosure. Furthermore, new technical features can be formed by combining the technical measures disclosed in the embodiments.

The present disclosure contains subject matter related to that disclosed in Japanese Priority Patent Application JP 2024-040391 filed in the Japan Patent Office on Mar. 14, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A drive circuit board comprising:
a circuit layer that includes a drive circuit; and
a drive electrode that forms layers together with the circuit layer and that is driven by a voltage applied from the drive circuit,
wherein the drive electrode includes a passive film having a first portion exposed to an outside on at least part of a surface of the drive electrode.

2. The drive circuit board according to claim 1, further comprising:
an edge cover that covers part of a peripheral portion of the drive electrode in plan view,
wherein the drive electrode has an exposed portion exposed from the edge cover at a center portion of the drive electrode in plan view, and
wherein the first portion is located at the exposed portion of the surface of the drive electrode.

3. The drive circuit board according to claim 2, wherein the edge cover has an oxide film on at least part of a surface of the edge cover.

4. The drive circuit board according to claim 2, wherein the passive film has a second portion located at least partially between the drive electrode and the edge cover.

5. The drive circuit board according to claim 4, further comprising:
an inorganic insulating layer located closer to the drive electrode than the circuit layer,
wherein the drive electrode and part of the edge cover are located on the inorganic insulating layer.

6. The drive circuit board according to claim 5, wherein the inorganic insulating layer has an oxide film on at least part of a surface of the inorganic insulating layer adjacent to the drive electrode.

7. The drive circuit board according to claim 1, wherein the drive electrode contains a metal, and the passive film is an oxide film located on at least part of the surface of the drive electrode.

8. The drive circuit board according to claim 7, wherein the drive electrode contains titanium, and the passive film contains titanium oxide.

9. The drive circuit board according to claim 1, wherein the drive electrode is provided in a plurality, and the drive circuit is provided in a plurality,
wherein the circuit layer includes the plurality of drive circuits each driving one of the plurality of drive electrodes, and
wherein each of the plurality of drive electrodes has the passive film on at least part of the surface of the drive electrode.

10. The drive circuit board according to claim 1, further comprising:
a first intervening layer between the drive electrode and the circuit layer;
a relay electrode that is electrically connected to the drive circuit via a first contact hole passing through the first intervening layer in a film thickness direction of the first intervening layer; and
a second intervening layer between the relay electrode and the drive electrode,
wherein the drive electrode is electrically connected to the relay electrode via a second contact hole passing through the second intervening layer in a film thickness direction of the second intervening layer.

11. The drive circuit board according to claim 1, further comprising:
a first intervening layer between the drive electrode and the circuit layer,
wherein the drive electrode is electrically connected to the drive circuit via a first contact hole passing through the first intervening layer in a film thickness direction of the first intervening layer.

12. A method for manufacturing a drive circuit board, comprising:
forming a circuit layer that includes a drive circuit; and
forming a drive electrode that forms layers together with the circuit layer and that is driven by a voltage applied from the drive circuit,
wherein the forming a drive electrode includes forming a passive film having a first portion exposed to an outside on at least part of a surface of the drive electrode.

13. The method according to claim 12, further comprising:
forming an edge cover that covers part of a peripheral portion of the drive electrode in plan view,
wherein the drive electrode has an exposed portion exposed from the edge cover at a center portion of the drive electrode in plan view, and
wherein the first portion is formed at the exposed portion in the forming a passive film.

14. The method according to claim 13, wherein the forming an edge cover includes forming an insulating film containing a material used for the edge cover and forming the exposed portion by patterning the insulating film.

15. The method according to claim 13, wherein the forming a passive film is performed after the forming an edge cover.

16. The method according to claim 13, wherein the forming a passive film is performed before the forming an edge cover.

17. The method according to claim 12, wherein the forming a passive film includes exposing a portion including a surface of the drive electrode to ozone water.

18. The method according to claim 12, wherein the forming a passive film includes exposing a portion including a surface of the drive electrode to oxygen plasma.

19. The method according to claim 12, wherein the forming a drive electrode includes forming a plurality of the drive electrodes,
wherein the forming a circuit layer includes forming a plurality of the drive circuits each driving one of the plurality of drive electrodes, and
wherein the forming a plurality of drive electrodes includes forming a conductive thin film containing a material used for the drive electrodes and patterning the conductive thin film.
